(19) United States
(12) Patent Application Publication
(10) Pub. No.: US 2026/0323896 A1
(43) Pub. Date: Oct. 15, 2026

(54) Protector for an Electronic Challenge Device

(71) Applicant: Paul Smith, Beaumont, CA (US)

(72) Inventor: Paul Smith, Beaumont, CA (US)

(21) Appl. No.: 19/646,499

(22) Filed: Apr. 13, 2026

Related U.S. Application Data
(60) Provisional application No. 63/788,099, filed on Apr. 13, 2025.

(51) Int. Cl. H05K 9/00; H05K 5/02; H05K 5/03

(52) U.S. Cl. CPC H05K 9/0007; H05K 5/0208; H05K 5/03; H05K 9/009

(57) ABSTRACT

A protective assembly for an electronic challenge device includes a base securely attached to a surface and a cover that is releasably coupled to the base. The cover comprises an exterior cover and an interior cover, with at least one thermal insulating layer and at least one electromagnetic shielding layer disposed between them. The exterior cover is fabricated from a durable material, such as aluminum, designed to withstand or absorb physical impacts. The thermal insulating layer restricts heat transfer using materials like aromatic polyamide-infused fibers, fiberglass, or carbon felt. The electromagnetic shielding layer utilizes conductive textiles to reflect airborne electromagnetic fields. Seals and a tight fit between components restrict water entry. The cover may be releasably joined to the base via a friction fit, a twist-to-lock mechanism, or a magnetic coupling.

### CROSS-REFERENCE TO RELATED APPLICATIONS

This application claims priority from U.S. Provisional Patent Application No. 63/788,099 filed on Apr. 13, 2025. The entire disclosure of the prior application is considered to be part of the disclosure of the accompanying application and is hereby incorporated by reference.

### BACKGROUND OF THE INVENTION

### 1. Field of the Invention

This invention relates to the field of protecting sensitive electronic devices from damage resulting from physical impacts, water, heat, or airborne electromagnetic waves. In particular, this invention is directed towards a cover for an electronic device that grants or denies access to a secure area or object and protects the electronic device from damage resulting from physical impacts, water, heat, or airborne electromagnetic waves.

### 2. Description of the Related Art

Secure areas, such as safes, vaults, rooms, or buildings, require a means to grant or deny access by presenting a challenge to users seeking entry. To gain access to the secure area, the user must overcome the challenge. Prior to advances in electronics and their associated control algorithms, physical keys or some form of memory-recall combination were used to challenge individuals seeking access. Over time, advances in electronic technology replaced physical keys and combinations with sophisticated biometric challenges, such as fingerprint, voiceprint, or iris and retina scanning, or even a simple challenge such as a 10-key keypad. Some of the benefits of using electronic challenges included ease of use; challenges could be easily edited if a user lost their access privileges; biometric challenges did not require the user to remember a code to overcome the challenge; and more.

At the same time, devices that use electronics to present a challenge have their own set of drawbacks. Electronic challenge devices are more susceptible to damage from a physical impact than mechanical challenge devices, such as keyholes or combination locks. When struck by an object, an electronic challenge device may be easily rendered useless. Electronic challenge devices are also susceptible to damage when exposed to water. Water may penetrate their outer housing and interfere with the proper flow of current, causing them to malfunction. Electronic challenge devices are also susceptible to high temperatures, as wiring insulation or plastics may deform. Deformed keys may be rendered inoperable, or insulation may deteriorate to the point where electronic circuits fail. Finally, electronic challenge devices are also susceptible to damage when exposed to strong electromagnetic fields that travel through the air. These airborne electromagnetic fields may be generated by lightning bolts, solar flares, or high-altitude nuclear bursts. When these fields come into contact with conductors found in electronic devices, a current will be induced. In extreme cases, the current can be so strong that the electronic challenge device may be damaged. Once a challenge device, mechanical or electrical, is damaged, access to the secure area is impaired, perhaps to the point where all are denied access. Immediate and costly maintenance may be required to regain access to the secure area.

It is difficult to retrofit an electronic challenge device to protect it against impact, water, heat, and electromagnetic fields. Often, this requires replacing the electronic challenge device with a more expensive, more rugged one. If there are multiple secure areas, the expense of replacing all of the electronic challenge devices, along with the cost of installation, may be prohibitive.

There exists a need for a protective add-on for existing electronic challenge devices that is low-cost, may be easily installed, provides protection against severe impacts, restricts the entry of water, is capable of insulating from high temperatures, and shields from airborne electromagnetic fields.

### BRIEF SUMMARY OF THE INVENTION

The present invention solves the problems identified above by utilizing a cover comprised of two components. The first component is a base that attaches to the surface on which the protected electronic challenge device is mounted. The second component is a cover that is releasably coupled to the base. Both the base and the cover may be made of a durable material, such as aluminum, that can withstand heavy impacts from objects. A seal between the base and the surface where the protected electronic challenge device is found restricts water from entering and damaging sensitive electronics. Additionally, a tight fit between the base and the cover will also restrict water from entering and damaging sensitive electronics. The cover may contain insulating material that restricts heat transfer to the protected electronic challenge device, preventing damage to plastics and other heat-sensitive materials. The insulating material may comprise aromatic polyamide-infused fibers, fiberglass, or carbon felt. The cover may also contain shielding material that is effective at preventing electromagnetic fields from passing through the cover and into the protected electronic challenge device. The shielding material may comprise metal fibers such as steel, copper, silver, or nickel, or cloth fibers coated with such metals.

The base may attach to the surface by any number of means, depending on the surface type. The means may include screws, bolts, adhesives, or any other means that enable the base to be securely attached to the surface. Securely attaching the base to the surface will prevent the base from being dislodged when struck by an object. Seals may be used between the base and the surface to ensure that the fit is such that water or other liquids will not seep through.

It is important that the cover be easily coupled and uncoupled from the base. By uncoupling the cover from the base, the user can access the protected electronic challenge device. By coupling the cover to the base, the electronic challenge device is protected from damage resulting from impact, water, heat, or electromagnetic fields. A variety of means are available to releasably join the base to the cover. One with ordinary skill in the art may utilize a simple friction fit between the base and cover. Other means may include “twist-to-lock,” where pins slide into “L” shaped slots, traditional threaded couplings, magnetic couplings, and more.

Neither this summary nor the following detailed description defines or limits the invention. The invention is defined by the claims.

### BRIEF DESCRIPTION OF DRAWINGS

FIG. 1A shows an isometric view of the present invention situated on a secure area with the cover uncoupled from the base and exposing the protected electronic challenge device.

FIG. 1B shows an isometric view of the present invention situated on a secure area with the cover coupled to the base. Here the protected electronic challenge device is enclosed and protected by the cover.

FIG. 2A shows an exploded isometric view of the first embodiment of the cover and its assembly.

FIG. 2B shows an isometric view of the first embodiment of the cover as a completed assembly.

FIG. 2C shows an exploded isometric view of the first embodiment of the base and its assembly.

FIG. 3A shows an isometric view of the second embodiment of the base.

FIG. 3B shows an isometric view of the second embodiment of the interior cover.

FIG. 4A shows an isometric view of the preferred embodiment of the base.

FIG. 4B shows an isometric view of the preferred embodiment of the interior cover.

### DETAILED DESCRIPTION OF THE INVENTION

The present invention will become more fully understood from the detailed description and accompanying drawings. Other systems, methods, features, and advantages of the invention will be or will become apparent to one with skill in the art upon examination of the following figures and detailed description. It is intended that all such additional systems, methods, features, and advantages be included within this description, be within the scope of the invention, and be protected by the accompanying claims. Components shown in the drawings are not necessarily to scale and may be exaggerated to better illustrate the important features of the invention. Dimensions disclosed or shown are exemplary only.

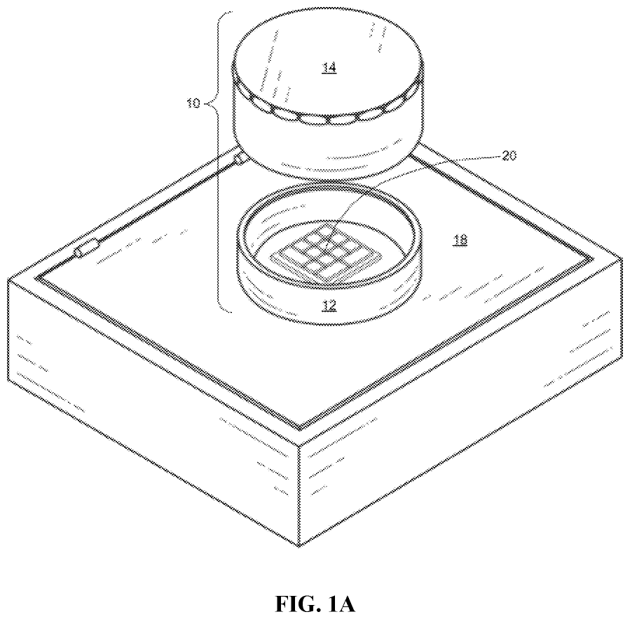

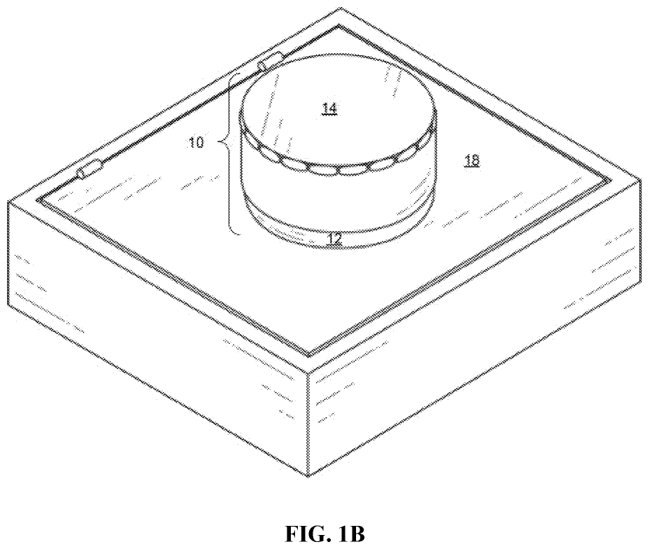

Referring now to FIG. 1A, the reader is shown an isometric view of the first embodiment with protective assembly 10 situated on secure area 18 with cover 14 uncoupled from base 12 and exposing electronic challenge device 20. The same view is also presented in FIG. 1B but with cover 14 being coupled to base 12 and thus enclosing electronic challenge device 20. In this embodiment, base 12 is affixed to the surface of secure area 18 by means of an adhesive. Other means to affix base 12 to the surface of secure area 18 will be described in the following paragraphs. Moreover, in this embodiment, cover 14 is releaseably coupled with base 12 by means of a friction fit. Other means to releaseably couple cover 14 and base 12 will be described in the following paragraphs. Although secure area 18 is shown as a safe, it is representative of a variety of secure areas, such as vaults, rooms, or buildings. A secure area is an area where only those users who satisfy the challenge presented by electronic challenge device 20, may access. In FIGS. 1A and 1B, the secure area is the interior of secure area 18. As discussed earlier, if electronic challenge device 20 fails, users are prevented from accessing the secure area. Electronic challenge device 20 may fail as a result of harm from an impact, by the penetration of water, from heat, or from an electromagnetic field.

In regard to preventing harm by impact, protective assembly 10 protects electronic challenge device 20 from impact because cover 14 may be fabricated from materials that repel or absorb the energy received from an impact, diverting the energy away from electronic challenge device 20. A widely used material is aluminum which is lightweight and durable. Aluminum may also be fabricated with an arrangement of internal air pockets that may absorb energy from an impact through deformation while also providing a degree of thermal protection. Other durable materials may also be used for cover 14 to provide electronic challenge device 20 protection from impacts. As a result, by fabricating cover 14 with a durable material that is able to withstand the impact or absorb the impact, electronic challenge device 20 itself is protected from physical impacts.

In regard to preventing harm from penetration by water, protective assembly 10 protects electronic challenge device 20 because when base 12 is affixed to the surface of secure area 18, a seal is formed that prevents water from entering protective assembly 10 between base 12 and the surface of secure area 18. Additionally, when cover 14 is coupled to base 12, a seal is formed that prevents water from entering protective assembly 10 between cover 14 and base 12. As a result, by preventing water from entering the enclosure bounded by protective assembly 10, electronic challenge device 20 is protected from harm that could result from water coming into contact with its circuits.

In regard to preventing harm from heat, protective assembly 10 protects electronic challenge device 20 because cover 14 may contain one or more layers of a thermal insulating material. Some thermal insulating materials may be shapable and designed to fit into cover 14. These materials include ceramics, plastics, and foams. Other thermal insulating materials may be in the form of a fabric made from silica, aerogel, or a carbon felt. Although carbon is a good conductor of heat, when engineered into a felt or a non-woven fabric, it provides excellent thermal insulation because of the millions of tiny air pockets that are created. Since air is a poor thermal conductor, the carbon felt becomes an insulator. As a result, by adding a carbon felt fabric to cover 14, electronic challenge device 20 is protected from exposure to heat that could be harmful to its plastics or its electronics.

In regard to preventing harm from electromagnetic fields, protective assembly 10 protects electronic challenge device 20 because cover 14 may contain one or more layers of an electromagnetic shielding material. In a high-altitude nuclear blast, the fastest-traveling electromagnetic field is referred to as the “E1” field. The E1 field travels at the speed of light and hits the ground almost instantaneously after the detonation. Gamma rays from the blast strip electrons off oxygen and nitrogen molecules in the atmosphere. These electrons are accelerated downward by the Earth's magnetic field, creating a very large and fast-rising electromagnetic field. Because E1 fields travel so quickly, standard surge protectors cannot react fast enough to block it. One way of shielding electronic circuits from electromagnetic fields is to surround the electronics with a metalized fabric, often referred to as a “Faraday Fabric.” A metalized fabric is constructed from a base fabric, typically nylon or polyester, or a non-woven fleece, with each thread coated with one or more layers of highly conductive metals such as nickel, copper, or silver or blends of the same. This creates a “conductive mesh” where the holes are smaller than the wavelength of the E1 pulse, effectively reflecting the E1 fields like a mirror. Moreover, multiple layers of a metalized fabric may be separated by a dielectric gap to exponentially increase shielding. Finally, conductive adhesive tapes, such as nickel-copper-based ones, may be used to ensure the shielding layer is continuous and free of holes. As a result, by adding a metalized fabric to cover 14, electronic challenge device 20 is protected from electromagnetic fields that could be harmful to its electronics.

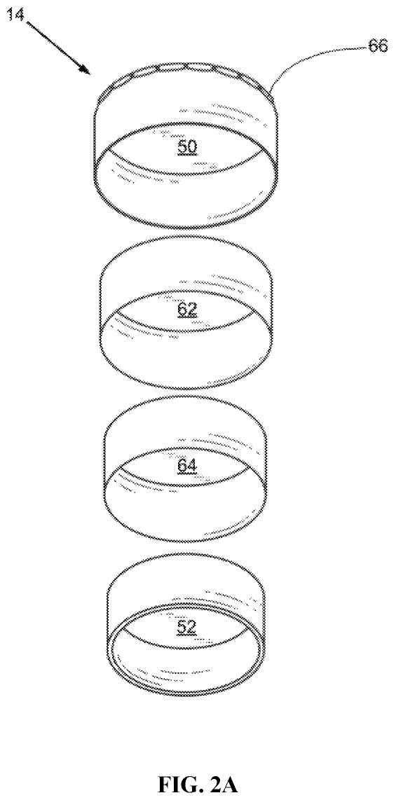

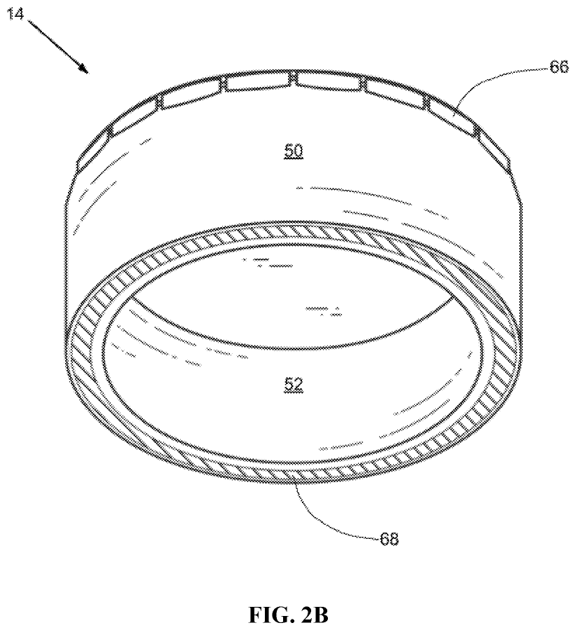

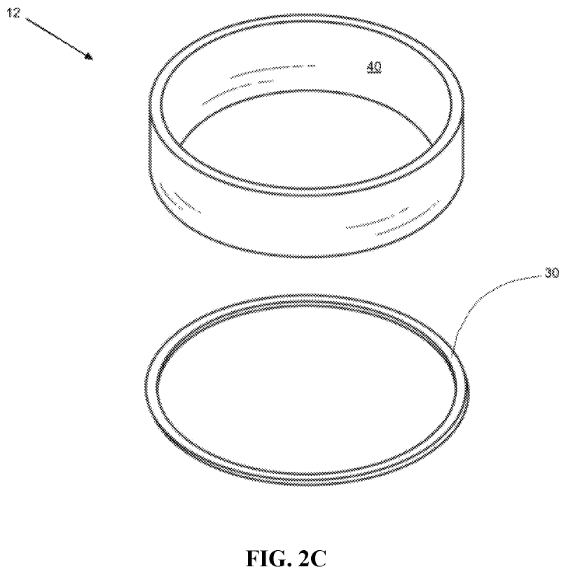

FIG. 2A and FIG. 2B shows the components of the first embodiment of protective assembly 10. FIG. 2A shows the components of cover 14, while FIG. 2B shows the components base 12. In the first embodiment of protective assembly 10, cover 14 is comprised of four components: exterior cover 50, first layer 62, second layer 64, and interior cover 52. The purpose of exterior cover 50 is to protect electronic challenge device 20 from physical impacts. In this disclosure, any discussion regarding the fabrication of cover 14 would also apply to the fabrication of exterior cover 50. Thus, it is exterior cover 50 that must be fabricated with a durable material capable of resisting strong impacts, or absorbing such impacts, so that electronic challenge device 20 is protected from such impacts. To assist the user in coupling or uncoupling cover 14 from base 12, grip 66 is provided. In FIG. 2A, grip 66 is depicted as a ribbed edge, but other approaches may be used to assist the user, such as a rubber ring about the edge of exterior cover 50. In FIG. 2A, only two protective layers shown: first layer 62 and second layer 64. protective assembly 10, at a minimum, will have at least two such layers, but more layers may be added. For example, in FIG. 2A, first layer 62 may be a thermal insulating layer while second layer 64 may be an electromagnetic shielding layer. In yet another configuration, first layer 62 may be an electromagnetic shielding layer while second layer 64 is a thermal insulating layer. In yet another configuration, cover 14 may be fabricated using three or more layers of thermal insulation and electromagnetic shielding materials. These layers may alternate between thermal insulating and electromagnetic shielding layers, or like layers may ajoin each other to form a thicker combined thermal insulating or electromagnetic shielding layer. Although FIG. 2A may only show two layers, first layer 62 and second layer 64 are representative of the fact that the thermal and electromagnetic shielding layers may take on many configurations. The purpose of interior cover 52 is to (i) provide an interface between cover 14 and base 12 and (ii) secure first layer 62 and second layer 64 within cover 14. In this embodiment, cover 14 engages with base 12 via a friction fit; thus, the inner diameter of interior cover 52 must be slightly larger than the exterior diameter of base 12. The exterior diameter of interior cover 52 is such that when interior cover 52 is inserted into exterior cover 50, first layer 62 and second layer 64 are secured between exterior cover 50 and interior cover 52. Additionally, adhesives may be used to secure the assembly of cover 14 or protrusions may be fabricated on the outer surface of interior cover 52 to secure the assembly of cover 14. FIG. 2B shows the completed assembly of cover 14 with interior cover 52 being inserted into exterior cover 50 and with layers 68 representing the layers in use for this particular configuration. FIG. 2C shows base 12 of the first embodiment. Here, base 12 is secured to the surface of secure area 18 by means of double-sided adhesive ring 30. Double-sided adhesive ring 30 may also function as a seal, preventing water from entering protective assembly 10 between base 12 and the surface.

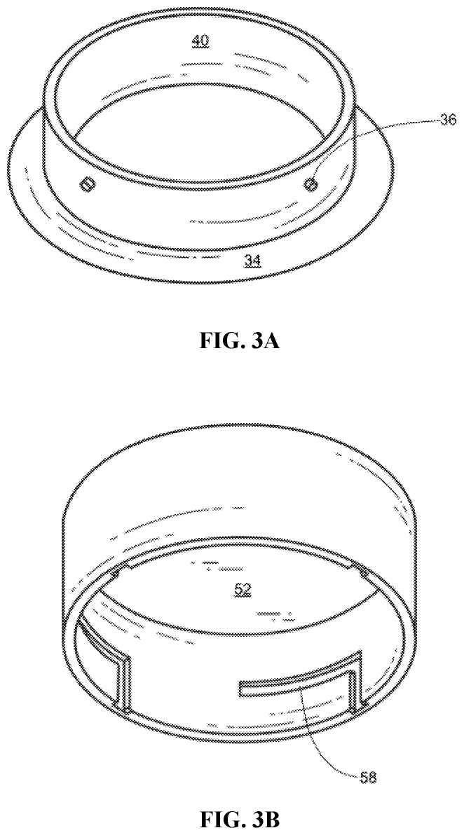

FIGS. 3A and 3B shows a second embodiment of protective assembly 10. What distinguishes the second embodiment from the first embodiment is how cover 14 couples with base 12. While the first embodiment, shown in the previous figures, used a friction fit between cover 14 and base 12, the second embodiment uses a twist-and-lock configuration. Here, lug 36 fabricated on support ring 40 are sized to slide into cut slots 58 fabricated on the interior wall of interior cover 52 so that the user may slide cover 14 over lug 36 found on support ring 40 and then twist cover 14 to couple it with base 12. The user may reverse these steps to uncouple cover 14 and base 12. Additionally, flange 34 found on support ring 40 may be used in multiple ways to secure base 12 to the surface of secure area 18. First, flange 34 provides a greater surface area than the first embodiment to attach adhesive ring 30. Therefore, a wider adhesive ring 30 may be used with the second embodiment as compared to the first embodiment. Additionally, holes in flange 34 may be used in conjunction with screws to mount support ring 40 to a suitable surface.

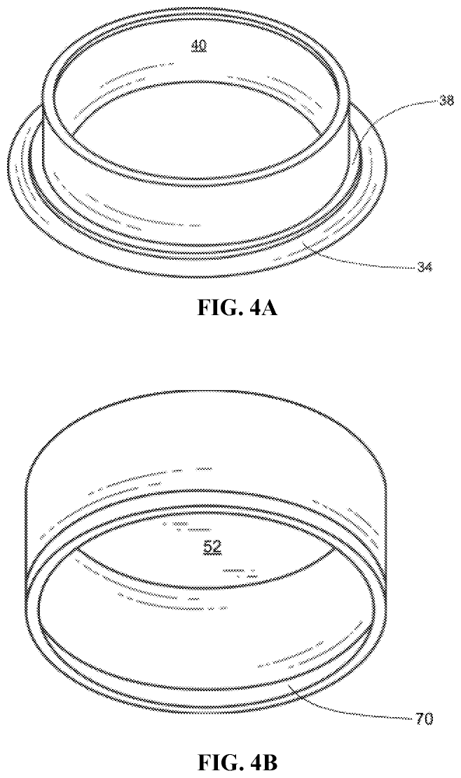

FIGS. 4A and 4B shows a third embodiment of protective assembly 10. What distinguishes the third embodiment from the first embodiment is how cover 14 couples with base 12. While the first embodiment, shown in the previous figures, used a friction fit between cover 14 and base 12, the third embodiment uses a configuration of magnets. Here, magnet 38 mounted on support ring 40 is arranged to attract magnet 70 mounted on interior cover 52. A user may slide cover 14 over base 12 so that magnet 70 and magnet 38 will couple cover 14 with base 12. The user may reverse these steps to uncouple cover 14 and base 12. The two magnet rings, magnet 38 and magnet 70, do not have to be complete rings as shown in FIG. 4A and FIG. 4B. A set of corresponding magnets may be arranged on support ring 40 that mate with a corresponding set of magnets on interior cover 52. In this case, interior cover 52 and support ring 40 may be configured with a set of mating tabs and grooves to properly align interior cover 52 with support ring 40. Additionally, flange 34 found on support ring 40 may be used in multiple ways to secure base 12 to the surface of secure area 18. First, flange 34 provides a greater surface area than the first embodiment to attach adhesive ring 30. Therefore, a wider adhesive ring 30 may be used with the third embodiment as compared to the first embodiment. Additionally, holes in flange 34 may be used in conjunction with screws to mount support ring 40 to a suitable surface.

The embodiments described above, including accompanying figures, are for illustrative purposes to explain aspects of the present invention. Those skilled in the art will recognize that changes and modifications can be made without departing from the scope of the invention. For example, various embodiments may be based on a wide range of different designs to couple cover 14 with base 12 or to arrange the thermal insulation and electromagnetic shielding layers between exterior cover 50 and interior cover 52. Therefore, the scope of the present invention shall be limited solely by the full scope of the following claims.

What is claimed is:

1. A protective assembly for an electronic challenge device mounted on a surface, the assembly comprising:
a base configured to be securely attached to the surface surrounding the electronic challenge device;
a cover configured to be releasably coupled to the base, the cover comprising an exterior cover and an interior cover;
at least one thermal insulating layer disposed between the exterior cover and the interior cover; and
at least one electromagnetic shielding layer disposed between the exterior cover and the interior cover.

2. The assembly of claim 1, wherein the exterior cover is comprised of a durable material configured to withstand or absorb physical impacts.

3. The assembly of claim 2, wherein the durable material is aluminum.

4. The assembly of claim 3, wherein the aluminum further comprises an arrangement of internal air pockets configured to absorb energy from an impact through deformation.

5. The assembly of claim 1, wherein the thermal insulating layer comprises at least one material selected from the group consisting of: aromatic polyamide-infused fibers, fiberglass, carbon felt, ceramics, plastics, foams, silica, and aerogel.

6. The assembly of claim 1, wherein the electromagnetic shielding layer comprises a metalized fabric.

7. The assembly of claim 6, wherein the metalized fabric comprises a base fabric where each thread is coated with at least one conductive metal selected from the group consisting of: nickel, copper, silver, and steel.

8. The assembly of claim 1, further comprising a seal disposed between the base and the surface to restrict the entry of water.

9. The assembly of claim 8, wherein the seal is a double-sided adhesive ring.

10. The assembly of claim 1, wherein the cover is releasably coupled to the base by a friction fit.

11. The assembly of claim 1, wherein the cover is releasably coupled to the base by a twist-to-lock configuration comprising at least one lug on the base and at least one corresponding slot on the interior wall of the interior cover.

12. The assembly of claim 1, wherein the cover is releasably coupled to the base by a magnetic coupling.

13. The assembly of claim 12, wherein the magnetic coupling comprises at least one magnet mounted on the base and at least one corresponding magnet mounted on the interior cover.

14. The assembly of claim 13, wherein the base and the interior cover further comprise structural elements to align the magnets mounted on the base to the magnets mounted on the interior cover.

15. The assembly of claim 1, wherein the exterior cover further comprises a grip to assist a user in coupling or uncoupling the cover from the base.
